(19) United States
(12) Patent Application Publication
(10) Pub. No.: US 2025/0040369 A1
(43) Pub. Date: Jan. 30, 2025

(54) SEMICONDUCTOR DEVICE, IMAGE FORMING DEVICE, DISPLAY DEVICE, PHOTOELECTRIC CONVERSION DEVICE, ELECTRONIC APPARATUS, ILLUMINATION DEVICE, MOVING BODY, AND WEARABLE DEVICE

(71) Applicant: Canon Kabushiki Kaisha, Tokyo (JP)

(72) Inventors: TETSUYA KIMURA, Tokyo (JP); KOUJI OZAKI, Kanagawa (JP)

(21) Appl. No.: 18/592,610

(22) Filed: Mar. 1, 2024

(30) Foreign Application Priority Data
Mar. 10, 2023 (JP) 2023-037030

(51) Int. Cl. H10K 59/131; H10K 59/121; H10K 59/80

(52) U.S. Cl. CPC H10K 59/131; H10K 59/1216; H10K 59/805

(57) ABSTRACT

A semiconductor device is provided. The device includes a first wiring layer including a first wiring pattern, a second wiring layer arranged between the first wiring layer and a surface of a substrate and including a second wiring pattern and a third wiring pattern, a first plug connecting the first wiring pattern and the second wiring pattern, a capacitive element including a first electrode arranged between the first wiring layer and the second wiring layer and a second electrode arranged at a position farther apart from the substrate than the first electrode, and a second plug connecting the first electrode and the third wiring pattern. An angle between a side surface of the second plug and an upper surface of the third wiring pattern is not more than 75°.

### BACKGROUND OF THE INVENTION

### Field of the Invention

The present invention relates to a semiconductor device, an image forming device, a display device, a photoelectric conversion device, an electronic apparatus, an illumination device, a moving body, and a wearable device.

### Description of the Related Art

Japanese Patent Laid-Open No. 2020-076841 shows a display device including a capacitive element with a MIM structure between two wiring layers.

### SUMMARY OF THE INVENTION

In the configuration shown in Japanese Patent Laid-Open No. 2020-076841, a plug connected to the electrode of the capacitive element is shorter than a plug that connects the two wiring layers. The plug is formed by burying a metal in a contact hole provided in an insulating layer and performing chemical mechanical polishing (CMP) for an unnecessary portion of the metal. The present inventors found that in the CMP process for forming the plug, if the plug is short, the plug may come out of the contact hole, or a gap may be generated between the plug and the contact hole, and this may lower yield in plug formation.

Some embodiments of the present invention provide a technique advantageous in forming a plug.

According to some embodiments, a semiconductor device comprising: a first wiring layer including a first wiring pattern; a second wiring layer arranged between the first wiring layer and a surface of a substrate and including a second wiring pattern and a third wiring pattern; a first plug connecting the first wiring pattern and the second wiring pattern; a capacitive element including a first electrode arranged between the first wiring layer and the second wiring layer and a second electrode arranged at a position farther apart from the substrate than the first electrode; and a second plug connecting the first electrode and the third wiring pattern, wherein an angle between a side surface of the second plug and an upper surface of the third wiring pattern is not more than 75°, is provided.

According to some other embodiments, a semiconductor device comprising: a first wiring layer including a first wiring pattern and a fourth wiring pattern; a second wiring layer arranged between the first wiring layer and a surface of a substrate and including a second wiring pattern; a first plug connecting the first wiring pattern and the second wiring pattern; a capacitive element including a second electrode arranged between the first wiring layer and the second wiring layer and a first electrode arranged between the second electrode and the substrate; and a third plug connecting the fourth wiring pattern and the second electrode, wherein an angle between a side surface of the third plug and an upper surface of the second electrode is not more than 75°, is provided.

Further features of the present invention will become apparent from the following description of exemplary embodiments (with reference to the attached drawings).

### BRIEF DESCRIPTION OF THE DRAWINGS

FIG. 1 is a view showing an example of the configuration of a semiconductor device according to an embodiment;

FIG. 2 is a circuit diagram showing an example of the configuration of a pixel arranged in the semiconductor device shown in FIG. 1;

FIG. 3 is a sectional view showing an example of the configuration of a pixel arranged in the semiconductor device shown in FIG. 1;

FIG. 4 is a sectional view showing an example of the configuration of a pixel arranged in the semiconductor device shown in FIG. 1;

FIG. 5A is a sectional view showing the shape of a plug arranged in the semiconductor device shown in FIG. 1, and FIG. 5B is a view showing a force applied to the side surface of the plug;

FIG. 6 is a sectional view showing an example of the configuration of a pixel arranged in the semiconductor device shown in FIG. 1;

FIG. 7 is a sectional view showing an example of the configuration of a pixel arranged in the semiconductor device shown in FIG. 1;

FIGS. 8A and 8B are sectional views showing an example of the configuration of the pixel of the semiconductor device shown in FIG. 1;

FIGS. 9A to 9C are views showing an example of an image forming device using the semiconductor device according to the embodiment;

FIG. 10 is a view showing an example of a display device using the semiconductor device according to the embodiment;

FIG. 11 is a view showing an example of a photoelectric conversion device using the semiconductor device according to the embodiment;

FIG. 12 is a view showing an example of an electronic apparatus using the semiconductor device according to the embodiment;

FIGS. 13A and 13B are views each showing an example of a display device using the semiconductor device according to the embodiment;

FIG. 14 is a view showing an example of an illumination device using the semiconductor device according to the embodiment;

FIG. 15 is a view showing an example of a moving body using the semiconductor device according to the embodiment; and

FIGS. 16A and 16B are views each showing an example of a wearable device using the semiconductor device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

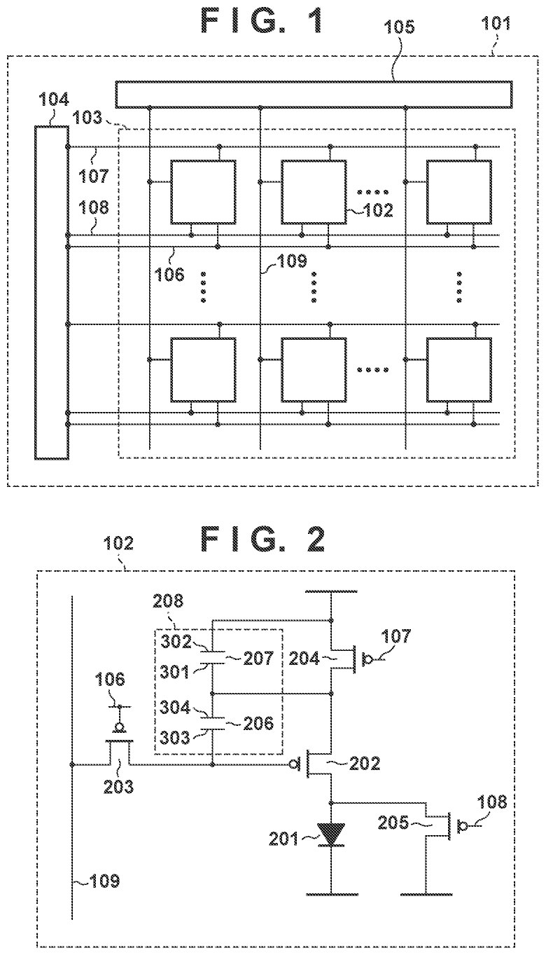

With reference to FIGS. 1 to 7, a semiconductor device according to an embodiment of the present disclosure will be described. In the embodiment to be described below, a description will be given while taking a light emitting device as an example of the semiconductor device. However, the present disclosure is not limited to this, and the present disclosure is applicable to a processing device, a storage device, a photoelectric conversion device, and the like, each including a semiconductor element, of various logic circuits, storage circuits, pixel circuits, and the like. More specifically, the present disclosure is applicable to all semiconductor devices to be described below, each of which includes a capacitive element and a plug connecting the electrode of the capacitive element and a wiring pattern.

FIG. 1 is a view showing an example of the configuration of a light emitting device 101 as an example of the semiconductor device in this embodiment. As shown in FIG. 1, the light emitting device 101 can include a pixel array portion 103, and a driving unit arranged around the pixel array portion 103. The pixel array portion 103 includes a plurality of pixels 102 arranged in an array on the side of a surface of a substrate, as will be described later. Each pixel 102 includes a light emitting element 201, as shown in FIG. 2. The light emitting element 201 may be, for example, an organic electroluminescence (EL) element that includes an anode and a cathode, and includes an organic layer including a light emitting layer between the anode and the cathode. The organic layer may appropriately include at least one of a hole injection layer, a hole transport layer, an electron injection layer, and an electron transport layer, in addition to the light emitting layer.

The driving unit is a circuit configured to drive the pixels 102 arranged in the pixel array portion 103. The driving unit can include, for example, a vertical scanning circuit 104 and a signal output circuit 105. Also, to supply signals from the driving unit to the pixels 102, scanning lines 106 to 108 extending along the row direction (the horizontal direction in FIG. 1) are arranged in the pixel array portion 103 in correspondence with the pixel rows of the pixels 102 arranged in an array. In addition, signal lines 109 extending along the column direction (the vertical direction in FIG. 1) are arranged in the pixel array portion 103 in correspondence with the pixel columns of the pixels 102 arranged in an array.

The scanning lines 106 to 108 are connected to the output terminals of the vertical scanning circuit 104 corresponding to the pixel rows. The signal lines 109 are connected to the output terminals of the signal output circuit 105 corresponding to the pixel columns.

The vertical scanning circuit 104 supplies a write control signal to the scanning line 106 when writing a luminance signal to each pixel 102 arranged in the pixel array portion 103. Also, the vertical scanning circuit 104 supplies, to the scanning line 107, a light emission control signal for driving the pixel 102 and causing it to emit light. Also, the vertical scanning circuit 104 supplies a reset signal for resetting the light emitting element 201 of the pixel 102 to the scanning line 108.

The signal output circuit 105 appropriately selects one of a luminance signal having a voltage according to luminance information when causing the light emitting element 201 of each pixel 102 to emit light and a reference voltage signal having a reference voltage and outputs it to the signal line 109. The luminance signal represents a luminance in each pixel 102 in an image displayed by the light emitting device 101 and can also be referred to as a video signal.

The circuit configuration of the pixel 102 according to this embodiment will be described next with reference to FIG. 2. Each of the plurality of pixels 102 arranged in the pixel array portion 103 can include the light emitting element 201, a driving transistor 202 configured to supply a current according to the luminance signal to the light emitting element 201, and a light emission control transistor 204 configured to control light emission or non-light emission of the light emitting element 201. The light emitting element 201, the driving transistor 202, and the light emission control transistor 204 form a current path. The light emission control transistor 204 controls light emission or non-light emission of the light emitting element 201 in accordance with a light emission control signal supplied to the scanning line 107 connected to the control terminal.

The pixel 102 can also include a write transistor 203 configured to transmit the luminance signal supplied to the signal line 109 to the control terminal of the driving transistor 202. The write transistor 203 is arranged between the signal line 109 and the control terminal of the driving transistor 202. More specifically, one of the main terminals of the write transistor 203 is connected to the control terminal of the driving transistor 202, as described above, and the other main terminal of the write transistor 203 is connected to the signal line 109. The control terminal of the write transistor 203 is connected to the scanning line 106 to which the write control signal is supplied. If the write transistor 203 is turned on in accordance with the write control signal, the luminance signal supplied to the signal line 109 is written in the control terminal of the driving transistor 202.

The pixel 102 can further include a reset transistor 205 configured to short-circuit two electrodes of the light emitting element 201 and reset it. The reset transistor 205 resets the light emitting element 201 in accordance with the reset signal supplied to the scanning line 108 connected to the control terminal.

The pixel 102 can also include a capacitive element 206 and a capacitive element 207. The capacitive elements 206 and 207 are arranged in the pixel 102 to hold the luminance signal written in the driving transistor 202. The capacitive element 206 includes an electrode 303 and an electrode 304. A dielectric body is arranged between the electrode 303 and the electrode 304. The capacitive element 207 includes an electrode 301 and an electrode 302. A dielectric body is arranged between the electrode 301 and the electrode 302. As shown in FIG. 2, the capacitive element 206 and the capacitive element 207 can form a capacitive element portion 208.

Here, the total number of transistors or capacitive elements arranged in the pixel 102 and the combination of the conductivity types of the transistors are merely examples, and are not limited to this configuration. For example, when implementing the pixel 102 with a smaller area, the reset transistor 205 may be omitted.

In addition, for example, another element may be arranged between the light emitting element 201 and the driving transistor 202 or between the driving transistor 202 and the light emission control transistor 204. In the configuration shown in FIG. 2, the driving transistor 202 is arranged between the light emitting element 201 and the light emission control transistor 204. However, the light emission control transistor 204 may be arranged between the light emitting element 201 and the driving transistor 202.

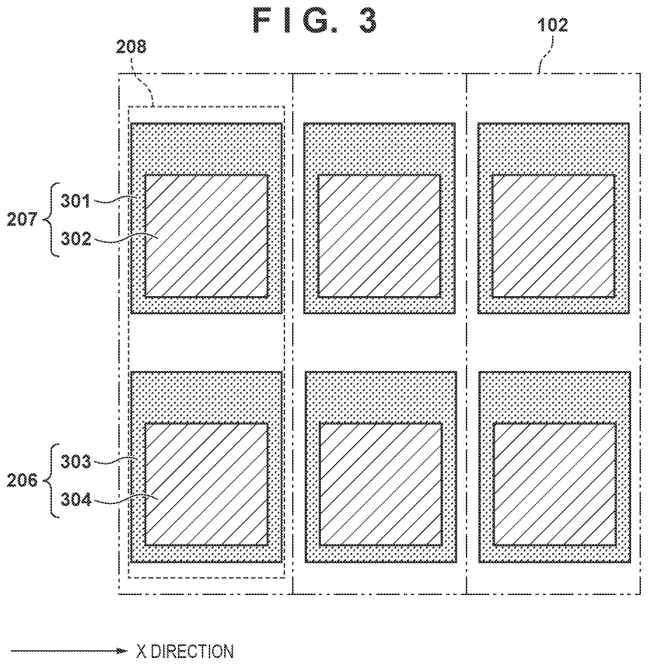

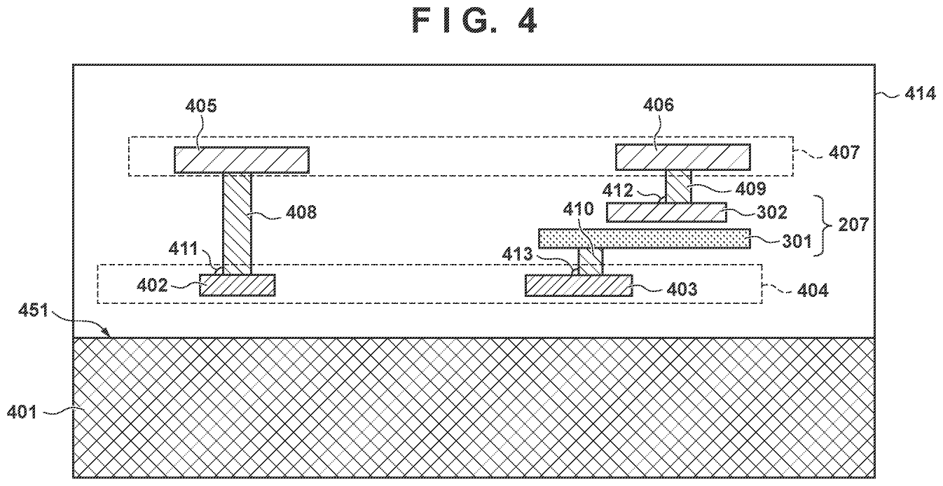

Details of the arrangement of the capacitive elements 206 and 207 will be described next with reference to FIGS. 3 and 4. FIG. 3 is an orthographic projection diagram of the capacitive element portion 208 arranged on the substrate. In FIG. 3, the capacitive element portions 208 of three pixels 102 are shown along the X direction that is the horizontal direction of the drawing. FIG. 4 is a sectional view including the capacitive element 207 arranged in the capacitive element portion 208, and a plug 408 arranged adjacent to the capacitive element 207. FIG. 4 shows the capacitive element 207, and the capacitive element 206 can have the same configuration. As described above, the capacitive elements 206 and 207 arranged in the pixel 102 of the light emitting device 101 will be described here as an example. The configuration of this embodiment can be applied to a semiconductor device in which a capacitive element is arranged between wiring layers each including a wiring pattern.

As shown in FIG. 4, an insulating body 414 is arranged on a surface 451 of a substrate 401. In the insulating body 414, a wiring layer 404 including wiring patterns 402 and 403 and a wiring layer 407 including wiring patterns 405 and 406 are arranged. The wiring layer 404 is arranged between the wiring layer 407 and a surface of the substrate 401. As the substrate 401, for example, a semiconductor substrate such as a silicon substrate is used. On the surface 451 of the substrate 401, various kinds of elements such as transistors such as the driving transistor 202, the write transistor 203, the light emission control transistor 204, and the reset transistor 205 described above and the capacitive elements 206 and 207 are arranged.

The wiring patterns 402 and 403 arranged in the wiring layer 404 are arranged in a direction along the surface 451 of the substrate 401. The wiring patterns 402 and 403 can be patterns that are simultaneously formed from one conductive layer using the same exposure and etching steps. For this reason, the upper surface of the wiring pattern 402 and the upper surface of the wiring pattern 403 can be arranged at the same height from the substrate 401 (surface 451). Here, the upper surface of the wiring pattern 402 is the surface of the wiring pattern 402 on a side apart from the substrate 401. In other configurations as well, “upper surface” indicates a similar surface. Also, the lower surface of the wiring pattern 402 and the lower surface of the wiring pattern 403 can be arranged at the same height from the substrate 401 (surface 451). Here, the lower surface of the wiring pattern 402 is the surface of the wiring pattern 402 on a side close to the substrate 401. In other configurations as well, “lower surface” indicates a similar surface.

Similarly, the wiring patterns 405 and 406 arranged in the wiring layer 407 are arranged in a direction along the surface 451 of the substrate 401. The wiring patterns 405 and 406 can be patterns that are simultaneously formed from one conductive layer using the same exposure and etching steps. For this reason, the upper surface of the wiring pattern 405 and the upper surface of the wiring pattern 406 can be arranged at the same height from the substrate 401 (surface 451). Also, the lower surface of the wiring pattern 405 and the lower surface of the wiring pattern 406 can be arranged at the same height from the substrate 401 (surface 451).

The wiring pattern 402 and the wiring pattern 405 are electrically connected by the plug 408. As shown in FIG. 4, the angle between the side surface of the plug 408 and the upper surface of the wiring pattern 402 is defined as an angle 411. Here, the side surface of the plug 408 is the surface that connects the upper surface and the lower surface of the plug 408. In other configurations as well, “side surface” indicates a similar surface.

The capacitive element 207 is arranged between the wiring layer 404 and the wiring layer 407. More specifically, the electrode 301 of the capacitive element 207 is arranged between the wiring layer 404 and the wiring layer 407. The electrode 302 of the capacitive element 207 is arranged at a position farther apart from the substrate 401 than the electrode 301. It can also be said that the electrode 301 is arranged between the electrode 302 and the surface of the substrate 401. In the configuration shown in FIG. 4, the electrode 302 is arranged between the wiring layer 404 and the wiring layer 407. It can also be said that the electrode 302 is arranged at a position farther apart from the substrate 401 than the electrode 301. The capacitive element 207 has a MIM structure formed by the electrode 301, the electrode 302, and a portion of the insulating body 414 arranged between the electrode 301 and the electrode 302.

The electrode 301 of the capacitive element 207 and the wiring pattern 403 arranged in the wiring layer 404 are connected by a plug 410. As shown in FIG. 4, the angle between the side surface of the plug 410 and the upper surface of the wiring pattern 403 is defined as an angle 413. The electrode 302 of the capacitive element 207 and the wiring pattern 406 arranged in the wiring layer 407 are connected by a plug 409. As shown in FIG. 4, the angle between the side surface of the plug 409 and the upper surface of the electrode 302 is defined as an angle 412.

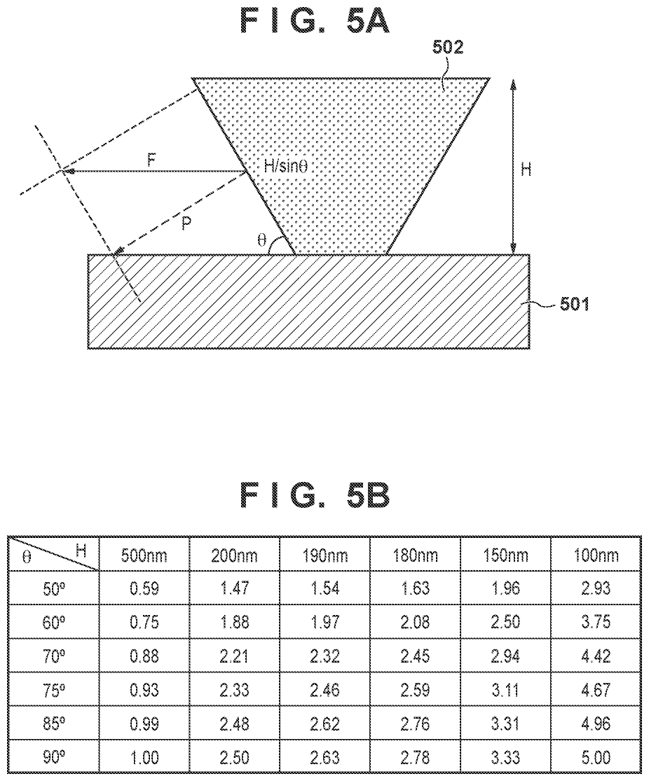

Next, a force applied to a plug when forming the plug by burying a metal in a contact hole provided in the insulating body and performing chemical mechanical polishing (CMP) for an unnecessary portion of the metal will be described with reference to FIGS. 5A and 5B. FIG. 5A shows a plug 502 formed on a wiring pattern 501. In the CMP step, the plug 502 receives a force F in a direction along the surface of the substrate from a polishing pad. Defining the force F and a height H of the plug 502 as parameters, a force P applied to the side surface of the plug 502 in contact with the insulating body can be represented by

$$P = F sin θ / ( H / sin θ ) \qquad ( 1 )$$

The angle θ is the angle between the upper surface of the wiring pattern 501 and the side surface of the plug 502.

Here, assume that the force F in the direction along the surface of the substrate, which the plug 502 receives from the polishing pad, is constant, and the force P applied to the side surface of the plug 502 when forming the plug 502 in a case where the height H of the plug is 500 nm and the angle θ is 90° is 1. FIG. 5B shows the force P applied to the plug side surface in a case where the angle θ and the height H of the plug 502 are changed under these conditions. The conditions that the interval between wiring layers is set to 500 nm, and a 500 nm long plug is arranged are conditions that are generally used.

As shown in FIG. 5B, it is found that the lower the height H of the plug 502 is, the larger the force P applied to the side surface of the plug 502 is. In addition, it is found that the larger the angle θ between the side surface of the plug 502 and the upper surface of the wiring pattern 501 is, the larger the force P applied to the side surface of the plug 502 is.

Experiments were conducted using copper as the wiring pattern 501 and tungsten as the plug 502. In this case, it is found that if a pattern formed by setting the height H of the plug 502 to 100 nm and the angle θ to 90° was planarized by CMP, the plug came out of the contact hole. The force P in this case is 5.00. Also, if a pattern formed by setting the height H of the plug to 190 nm and the angle θ to 90° was planarized by CMP, a space was generated between the plug 502 and the contact hole in which the plug 502 was buried, and the copper contained in the wiring pattern 501 was deposited. The force P in this case is 2.63. On the other hand, if a pattern formed by setting the height H of the plug to 200 nm and the angle θ to 90° was planarized by CMP, the plug could be formed with high yield. The force P in this case is 2.50. Hence, lowering of the yield in forming the plug 502 can be suppressed by setting the height H of the plug 502 and the angle θ such that the force P is 2.50 or less.

In the capacitive element 207 arranged between the wiring layer 404 and the wiring layer 407, the plugs 409 and 410 have the height H lower than that of the plug 408. For this reason, if the angle 413 between the side surface of the plug 410 and the upper surface of the wiring pattern 403 is set to the above-described angle θ, the height of the plug 410 is set to the above-described height H, and a relationship given by

$$( 500 / H ) {sin}^{2} θ \leq 2.5 \qquad ( 2 )$$

is satisfied based on expression (1), occurrence of a fault when forming the plug 410 can be suppressed. Similarly, if the angle 412 between the side surface of the plug 409 and the upper surface of the electrode 302 is set to the above-described angle θ, the height of the plug 409 is set to the above-described height H, and the relationship of expression (2) is satisfied, occurrence of a fault when forming the plug 409 can be suppressed.

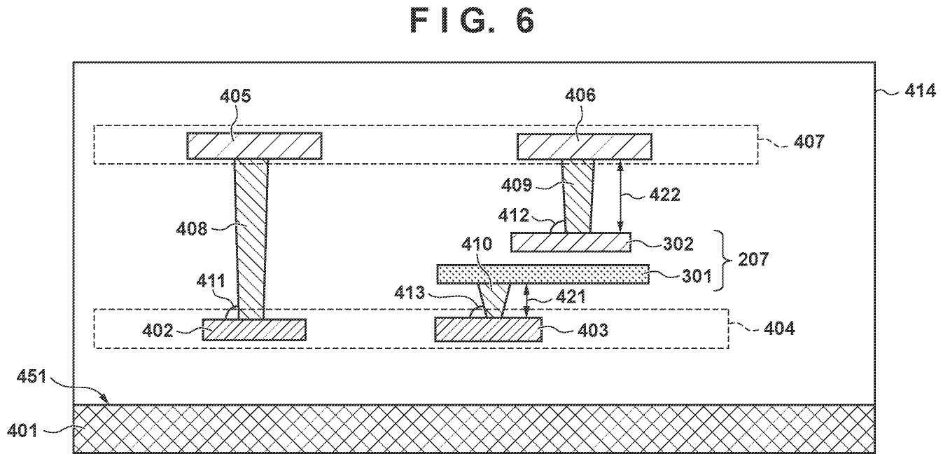

A more detailed configuration of this embodiment will be described next. As shown in FIG. 6, the wiring layer 404 including the wiring patterns 402 and 403 is formed using copper on the surface 451 of the substrate 401 on which transistors (not shown) are formed. The wiring layer 407 including the wiring patterns 405 and 406 using copper is formed at a position farther apart from the substrate 401 than the wiring layer 404. The capacitive element 207 with the MIM structure including the electrodes 301 and 302 is formed between the wiring layer 404 and the wiring layer 407.

Copper may be buried in the plug 408 connecting the wiring pattern 402 and the wiring pattern 405. For example, the wiring pattern 405 and the plug 408 may have a dual damascene structure. In this case, when forming the wiring pattern 405 and the plug 408, the wiring pattern 406 and the plug 409 may be formed simultaneously. Hence, the wiring pattern 406 and the plug 409 may have a dual damascene structure and contain copper. If the wiring pattern 406 and the plug 409 are formed using dual damascene, the force applied to the plug 409 in the CMP step is small, and occurrence of a fault associated with the plug 409 can be suppressed.

On the other hand, tungsten may be buried in the plug 410 connecting the electrode 301 and the wiring pattern 403. When forming the plug 410, tungsten is buried in the contact hole in which the plug 410 is arranged, and tungsten outside the contact hole is polished by CMP. In this case, the shape of the plug 410 is decided such that the relationships of expressions (1) and (2) described above are satisfied, thereby suppressing occurrence of a fault when forming the plug 410.

For example, the angle 413 between the side surface of the plug 410 and the upper surface of the wiring pattern 403 is set to 70°, a height 421 of the plug 410 is set to 200 nm, and the plug 410 is formed such that a width of the plug 410 in a direction parallel to the surface of the substrate 401 increases as a distance between the width of the plug 410 and the surface of the substrate 401 increases. Thus, the above-described force P is 2.21 that is smaller than 2.50. This embodiment can obtain a large effect when the height 421 of the plug 410 is as low as, for example, 200 nm or less.

As shown in FIG. 5B, when the angle 413 between the side surface of the plug 410 and the upper surface of the wiring pattern 403 is set to 75° or less, a fault when forming the plug 410 can be suppressed even if the height 421 of the plug 410 is low. On the other hand, if the upper surface of the plug 410 is large, microfabrication of the pixel 102 may be difficult. For this reason, the aspect ratio between the height 421 of the plug 410 and the surface of the plug 410 in contact with the electrode 301 may be 1 or less. For example, if the height 421 of the plug 410 is 200 nm, and the plug 410 has a columnar shape, the diameter of the plug 410 may be 200 nm or less in an orthographic projection to the surface 451 of the substrate 401. Also, for example, if the height 421 of the plug 410 is 200 nm, and the plug 410 has a rectangular parallelepiped shape, the length of one side or diagonal line of the plug 410 may be 200 nm or less in an orthographic projection to the surface 451 of the substrate 401. This can suppress the upper surface of the plug 410 becoming too large. From the viewpoint of the size of the upper surface of the plug 410, the angle 413 between the side surface of the plug 410 and the upper surface of the wiring pattern 403 may be, for example, 40° or more, may be, for example, 45° or more, or may be, for example, 50° or more.

As shown in FIG. 6, the angle 411 between the side surface of the plug 408 and the upper surface of the wiring pattern 402 may be larger than the angle 413 between the side surface of the plug 410 and the upper surface of the wiring pattern 403. The height of the plug 408 is higher than the plug 410. For this reason, even if the plug 408 is formed by burying tungsten or the like, the force P in the CMP step is smaller than that for the plug 410.

Also, in a case where the plug 409 and the wiring pattern 406 are formed by dual damascene, the angle 412 between the side surface of the plug 409 and the upper surface of the electrode 302 may be larger than the angle 413 between the side surface of the plug 410 and the upper surface of the wiring pattern 403. Also, for example, if a height 422 of the plug 409 is higher than the height 421 of the plug 410, the angle 412 may be larger than the angle 413. For example, the angle 411 between the side surface of the plug 408 and the upper surface of the wiring pattern 402 and the angle 412 between the side surface of the plug 409 and the upper surface of the electrode 302 may be larger than the angle 413 between the side surface of the plug 410 and the upper surface of the wiring pattern 403.

In the configuration shown in FIG. 6, the electrode 302 is arranged between the wiring layer 407 and the electrode 301. However, the present invention is not limited to this. The electrode 302 may be arranged in the wiring layer 407. This can make the height 421 of the plug 410 higher than in the configuration shown in FIG. 6.

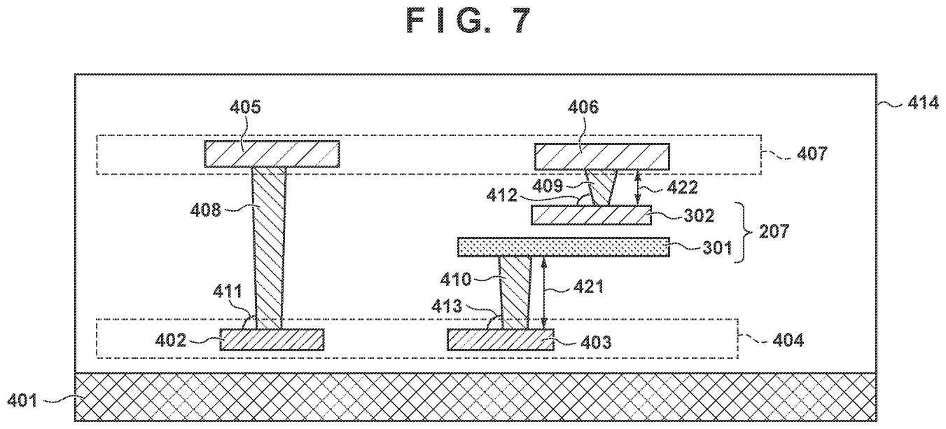

FIG. 7 shows a modification of the configuration shown in FIG. 6. In the configuration shown in FIG. 7, the height 422 of the plug 409 is lower than the height 421 of the plug 410. Also, tungsten is buried as the plug 409. For this reason, when forming the plug 409, tungsten is buried in the contact hole in which the plug 409 is arranged, and tungsten outside the contact hole is polished by CMP. In this case, the shape of the plug 409 is decided such that the relationships of expressions (1) and (2) described above are satisfied, thereby suppressing occurrence of a fault when forming the plug 409.

For example, the angle 412 between the side surface of the plug 409 and the upper surface of the electrode 302 is set to 70°, the height 422 of the plug 409 is set to 200 nm, and the plug 409 is formed such that a width of the plug 409 in the direction parallel to the surface of the substrate 401 increases as a distance between the width of the plug 409 and the surface of the substrate 401 increases. Thus, the above-described force P is 2.21 that is smaller than 2.50. This embodiment can obtain a large effect when the height 422 of the plug 409 is as low as, for example, 200 nm or less.

As shown in FIG. 5B, when the angle 412 between the side surface of the plug 409 and the upper surface of the electrode 302 is set to 75° or less, a fault when forming the plug 409 can be suppressed even if the height 422 of the plug 409 is low. On the other hand, if the upper surface of the plug 409 is large, microfabrication of the pixel 102 may be difficult. For this reason, the aspect ratio between the height 422 of the plug 409 and the surface of the plug 409 in contact with the wiring pattern 406 may be 1 or less. For example, if the height 422 of the plug 409 is 200 nm, and the plug 409 has a columnar shape, the diameter of the plug 409 may be 200 nm or less in an orthographic projection to the surface 451 of the substrate 401. Also, for example, if the height 422 of the plug 409 is 200 nm, and the plug 409 has a rectangular parallelepiped shape, the length of one side or diagonal line of the plug 409 may be 200 nm or less in an orthographic projection to the surface 451 of the substrate 401. This can suppress the upper surface of the plug 409 becoming too large. From the viewpoint of the size of the upper surface of the plug 410, the angle 412 between the side surface of the plug 409 and the upper surface of the electrode 302 may be, for example, 40° or more, may be, for example, 45° or more, or may be, for example, 50° or more.

In the configuration shown in FIG. 7, the electrode 301 and the plug 410 may have a dual damascene structure and contain copper. If the electrode 301 and the plug 410 are formed using dual damascene, the force applied to the plug 410 in the CMP step is small, occurrence of a fault associated with the plug 410 can be suppressed.

As shown in FIG. 7, the angle 411 between the side surface of the plug 408 and the upper surface of the wiring pattern 402 may be larger than the angle 412 between the side surface of the plug 409 and the upper surface of the electrode 302. The height of the plug 408 is higher than the plug 410. For this reason, even if the plug 408 is formed by burying tungsten or the like, the force P in the CMP step is smaller than that for the plug 409.

Also, in a case where the height 422 of the plug 409 is higher than the height 421 of the plug 410, the angle 413 between the side surface of the plug 410 and the upper surface of the wiring pattern 403 may be larger than the angle 412 between the side surface of the plug 409 and the upper surface of the electrode 302. For example, the angle 411 between the side surface of the plug 408 and the upper surface of the wiring pattern 402 and the angle 412 between the side surface of the plug 409 and the upper surface of the electrode 302 may be larger than the angle 413 between the side surface of the plug 410 and the upper surface of the wiring pattern 403.

In the configuration shown in FIG. 7, the electrode 301 is arranged between the wiring layer 404 and the electrode 302. However, the present invention is not limited to this. The electrode 301 may be arranged in the wiring layer 404. This can make the height 422 of the plug 409 higher than in the configuration shown in FIG. 7.

In the configurations shown in FIGS. 6 and 7, one of the plug 410 and the plug 409 has a shape satisfying the above-described expressions (1) and (2) in which the angle 413 or 412 is, for example, 75° or less. However, the present invention is not limited to this. For example, each of the angle 413 between the plug 410 and the upper surface of the wiring pattern 403 and the angle 412 between the side surface of the plug 409 and the upper surface of the electrode 302 may be 75° or less. In addition, each of the height 421 of the plug 410 and the height 422 of the plug 409 may be 200 nm or less and, for example, each of the plug 410 and the plug 409 may contain tungsten. Furthermore, for example, each of the aspect ratio between the height 421 of the plug 410 and the surface of the plug 410 in contact with the electrode 301 and the aspect ratio between the height 422 of the plug 409 and the surface of the plug 409 in contact with the wiring pattern 406 may be 1 or less, and for example, each of the relationship between the angle 413 (θ) and the height 421 (H) and the relationship between the angle 412 (θ) and the height 422 (H) may satisfy expressions (1) and (2).

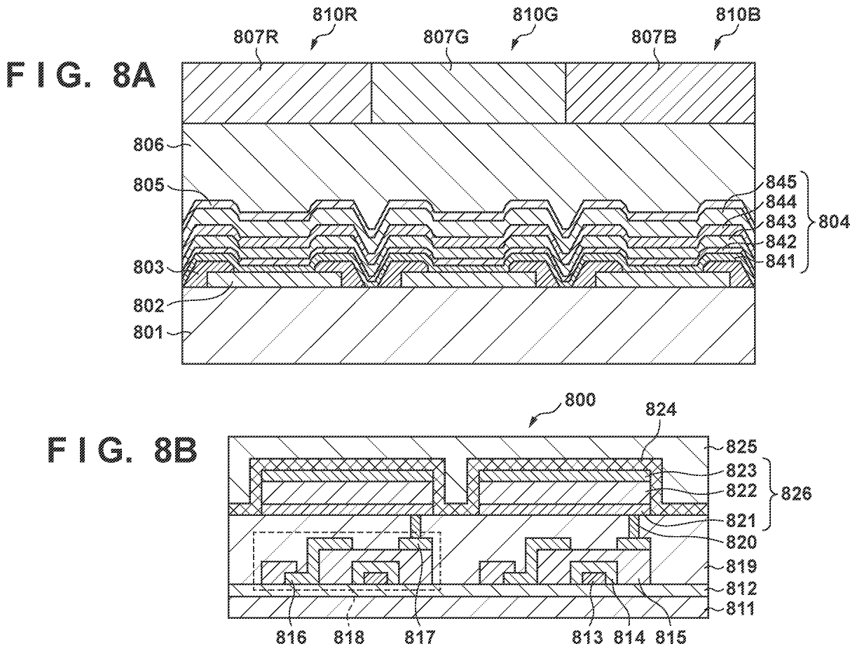

Here, application examples in which the semiconductor device serving as the light emitting device 101 according to the embodiment is applied to an image forming device, a display device, a photoelectric conversion device, an electronic apparatus, an illumination device, a moving body, and a wearable device will be described here with reference to FIGS. 8A and 8B to 16A and 16B. The description will be given assuming that, for example, an organic light emitting element such as an organic EL element is arranged as the light emitting element 201 in the pixel 102 arranged in the pixel array portion 103 of the light emitting device 101 as has been described above. Details of each component arranged in the pixel array portion 103 of the light emitting device 101 described above will be described first, and the application examples will be described after that.

### Configuration of Organic Light Emitting Element

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case in which a planarizing layer is provided between the color filter and the microlens.

### Substrate

Quartz, glass, a silicon wafer, a resin, a metal, or the like may be used as a substrate. Furthermore, a switching element such as a transistor, a wiring pattern, and the like may be provided on the substrate, and an insulating layer may be provided thereon. The insulating layer may be made of any material as long as a contact hole can be formed so that the wiring pattern can be formed between the first electrode and the substrate and insulation from the unconnected wiring pattern can be ensured. For example, a resin such as polyimide, silicon oxide, silicon nitride, or the like may be used for the insulating layer.

### Electrode

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

If the electrode is used as a reflective electrode, for example, chromium, aluminum, silver, titanium, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

### Pixel Isolation Layer

A pixel isolation layer may be formed by a so-called silicon oxide, such as silicon nitride (SiN), silicon oxynitride (SiON), or silicon oxide (SiO), formed using a Chemical Vapor Deposition (CVD) method. To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, the taper angle of the side wall of the pixel isolation layer or the film thickness of the pixel isolation layer can be adjusted to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer may be 10 nm (inclusive) to 150 nm (inclusive). A similar effect can be obtained in a configuration including only pixel electrodes without the pixel isolation layer. However, in this case, the film thickness of the pixel electrode is set to be equal to or smaller than half the film thickness of the organic layer or the end portion of the pixel electrode is formed to have a forward tapered shape of less than 60° With this, short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting device may include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this configuration, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

### Application of Organic Light Emitting Element of Embodiment of Present Disclosure

The organic light emitting element according to an embodiment of the present disclosure can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

More details will be described next with reference to the accompanying drawings. FIG. 8A shows an example of a pixel as a constituent element of the above-described pixel array portion 103. The pixel includes sub-pixels 810 (pixels 102). The sub-pixels are divided into sub-pixels 810R, 810G, and 810B by emitted light components. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include a plurality of layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

A display device 800 (corresponding to the above-described light emitting device 101) shown in FIG. 8B is provided with an organic light emitting element 826 and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 8B. That is, one of the anode and cathode and one of the source electrode and drain electrode of the TFT are electrically connected. The TFT indicates a thin-film transistor.

In the display device 800 shown in FIG. 8B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the display device 800 shown in FIG. 8B but may be used as another switching element.

The transistor used in the display device 800 shown in FIG. 8B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display device 800 shown in FIG. 8B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Here, the switching element according to this embodiment is not limited to the TFT, and may be a transistor formed from low-temperature polysilicon or an active matrix driver formed on the substrate such as a silicon substrate. The term “on the substrate” may mean “in the substrate”. Whether to provide a transistor in the substrate or use a TFT is selected based on the size of the display unit. For example, if the size is about 0.5 inch, the organic light emitting element may be provided on the silicon substrate.

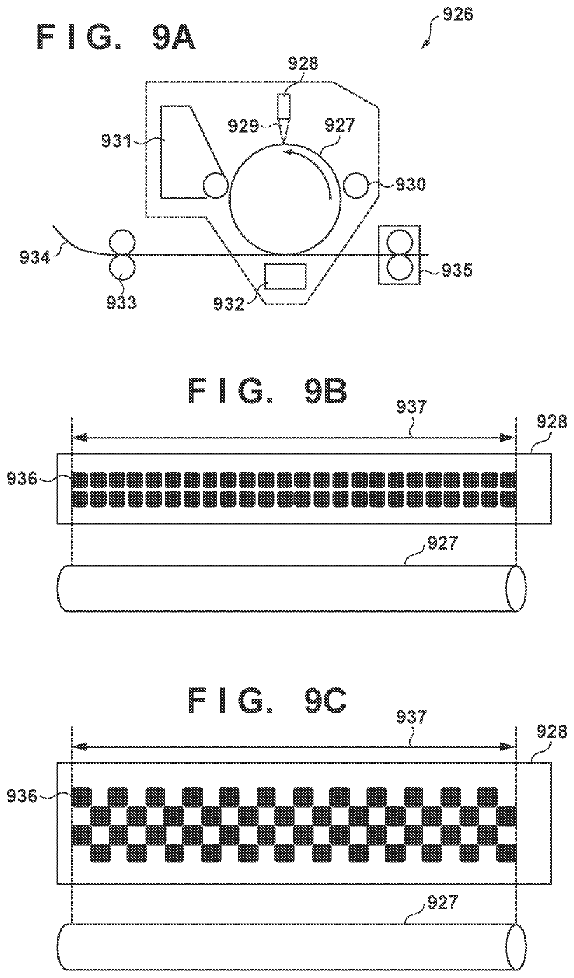

FIGS. 9A to 9C are schematic views showing an example of an image forming device using the light emitting device 101 according to this embodiment. An image forming device 926 shown in FIG. 9A includes a photosensitive member 927, an exposure light source 928, a developing unit 931, a charging unit 930, a transfer device 932, a conveyance unit 933 (a conveyance roller in the configuration shown in FIG. 9A), and a fixing device 935.

Light 929 is emitted from the exposure light source 928, and an electrostatic latent image is formed on the surface of the photosensitive member 927. The light emitting device 101 can be applied to the exposure light source 928. The developing unit 931 can function as a developing device that contains a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 can be, for example, paper or a film. The fixing device 935 fixes the image formed on the print medium.

Each of FIGS. 9B and 9C is a schematic view showing a plurality of light emitting units 936 arranged along the longitudinal direction on a long substrate in the exposure light source 928. The light emitting device 101 can be applied to the light emitting units 936. That is, the plurality of pixels 102 arranged in the pixel array portion 103 are arranged along the longitudinal direction of the substrate. A direction 937 is a direction parallel to the axis of the photosensitive member 927. This column direction matches the direction of the axis upon rotating the photosensitive member 927. This direction 937 can be referred to as the long-axis direction of the photosensitive member 927.

FIG. 9B shows a form in which the light emitting units 936 are arranged along the long-axis direction of the photosensitive member 927. FIG. 9C shows a form, which is a modification of the arrangement of the light emitting units 936 shown in FIG. 9B, in which the light emitting units 936 are arranged in the column direction alternately between the first column and the second column. The light emitting units 936 are arranged at different positions in the row direction between the first column and the second column. In the first column, multiple light emitting units 936 are arranged spaced apart from each other. In the second column, the light emitting unit 936 is arranged at the position corresponding to the gap between the light emitting units 936 in the first column. Also in the row direction, multiple light emitting units 936 are arranged spaced apart from each other. The arrangement of the light emitting units 936 shown in FIG. 9C can be referred to as, for example, an arrangement in a grid pattern, an arrangement in a staggered pattern, or an arrangement in a checkered pattern.

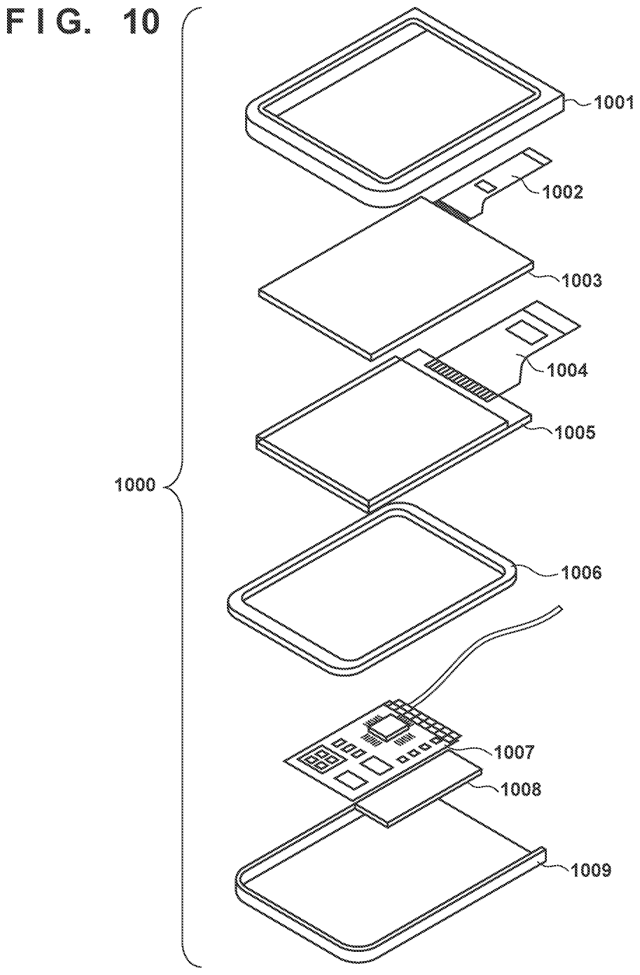

FIG. 10 is a schematic view showing an example of the display device using the light emitting device 101 of this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. Even when the display device 1000 is a portable apparatus, the battery 1008 need not be provided at this position. The light emitting device 101 can be applied to the display panel 1005. The pixels 102 arranged in the pixel array portion 103 of the light emitting device 101 functioning as the display panel 1005 operate in a state in which they are connected to the active elements such as transistors arranged on the circuit board 1007.

The display device 1000 shown in FIG. 10 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

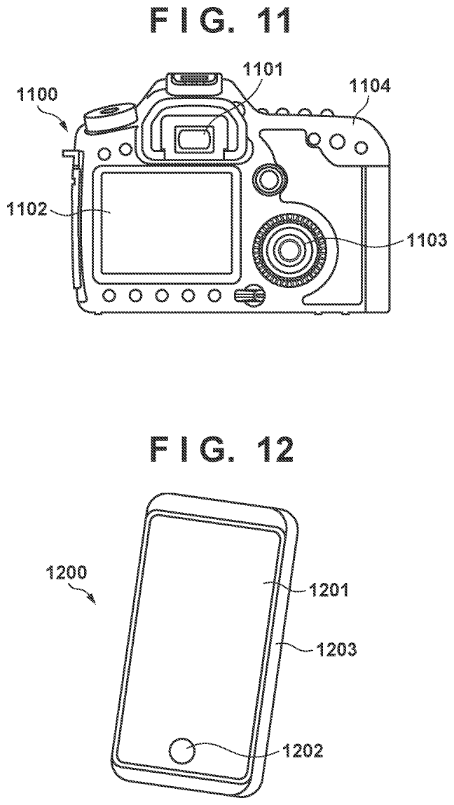

FIG. 11 is a schematic view showing an example of the photoelectric conversion device using the light emitting device 101 of this embodiment. A photoelectric conversion device 1100 can include a viewfinder 1101, a rear display 1102, an operation unit 1103, and a housing 1104. The photoelectric conversion device 1100 can also be called an image capturing device. The light emitting device 101 according to this embodiment can be applied to the viewfinder 1101 or the rear display 1102 as a display unit. In this case, the pixel array portion 103 of the light emitting device 101 can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time in many cases, so the information should be displayed as soon as possible. Therefore, the light emitting device 101 in which the pixel 102 including the light emitting element using the organic light emitting material such as an organic EL element is arranged in the pixel array portion 103 may be used for the viewfinder 1101 or the rear display 1102. This is so because the organic light emitting material has a high response speed. The light emitting device 101 using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 101 may be applied to a display unit of an electronic apparatus. At this time, the display unit can have both a display function and an operation function. Examples of the portable terminal are a portable phone such as a smartphone, a tablet, and a head mounted display.

FIG. 12 is a schematic view showing an example of an electronic apparatus using the light emitting device 101 of this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 101 according to this embodiment can be applied to the display unit 1201.

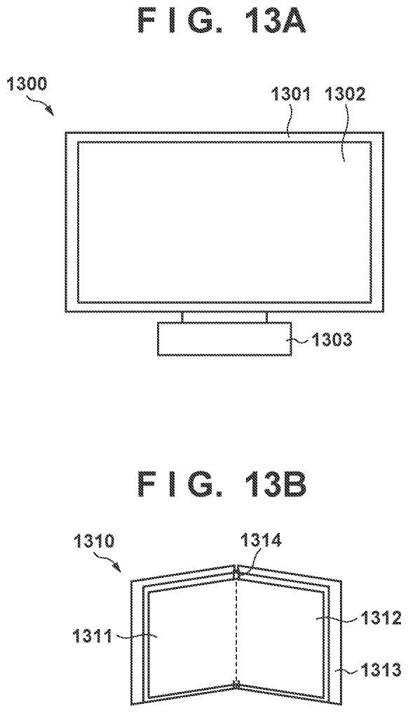

FIGS. 13A and 13B are schematic views showing examples of the display device using the light emitting device 101 of this embodiment. FIG. 13A shows a display device such as a television monitor or a PC monitor. A display device 1300 includes a frame 1301 and a display unit 1302. The light emitting device 101 according to this embodiment can be applied to the display unit 1302. The display device 1300 can include a base 1303 that supports the frame 1301 and the display unit 1302. The base 1303 is not limited to the form shown in FIG. 13A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 13B is a schematic view showing another example of the display device using the light emitting device 101 of this embodiment. A display device 1310 shown in FIG. 13B can be folded, and is a so-called foldable display device. The display device 1310 includes a first display unit 1311, a second display unit 1312, a housing 1313, and a bending point 1314. The light emitting device 101 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

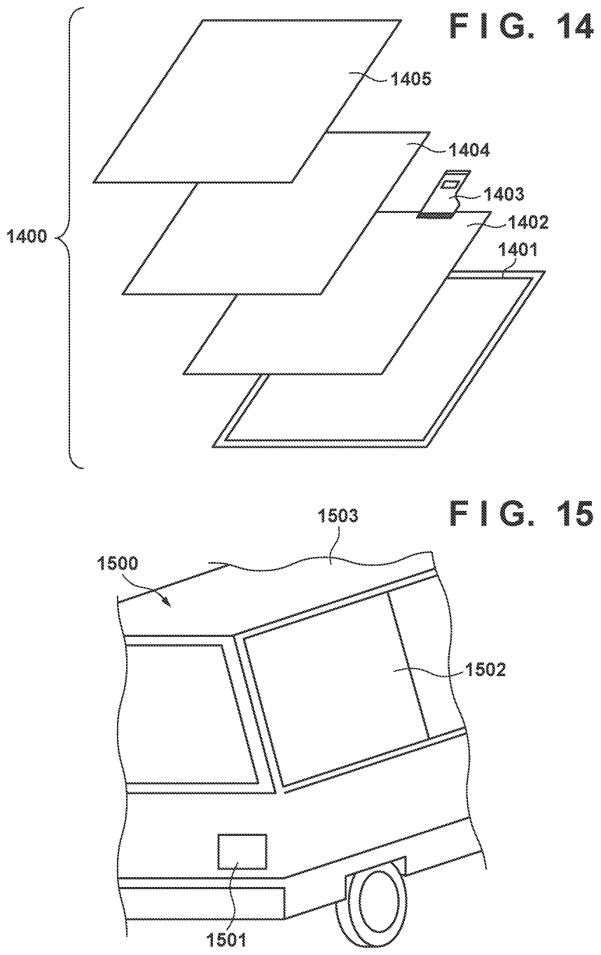

FIG. 14 is a schematic view showing an example of an illumination device using the light emitting device 101 according to this embodiment. An illumination device 1400 may include a housing 1401, a light source 1402, a circuit board 1403, an optical film 1404, and a light diffusion unit 1405. The light emitting device 101 according to this embodiment can be applied to the light source 1402. The optical film 1404 may be a filter that improves the color rendering property of the light source. The light diffusion unit 1405 can effectively diffuse light from the light source to illuminate a wide range for lighting up or the like. A cover may be provided in the outermost portion, as needed. The illumination device 1400 may include both the optical film 1404 and the light diffusion unit 1405, or may include only one of them.

The illumination device 1400 is, for example, a device that illuminates a room. The illumination device 1400 may emit light of white, day white, or any other color from blue to red. The illumination device 1400 may include a light control circuit for controlling the light color. The illumination device 1400 may include a power supply circuit connected to the light emitting device 101 which functions as the light source 1402. The power supply circuit is a circuit that converts an AC voltage into a DC voltage. Note that white light has a color temperature of 4200K, and day-white light has a color temperature of 5000K. The illumination device 1400 may also include a color filter. Further, the illumination device 1400 may include a heat dissipation portion. The heat dissipation portion releases the heat in the device to the outside of the device, and examples thereof include a metal having high specific heat, liquid silicon, and the like.

FIG. 15 is a schematic view showing an automobile including a tail lamp which is an example of the lighting unit for an automobile using the light emitting device 101 according to this embodiment. An automobile 1500 includes a tail lamp 1501, and may turn on the tail lamp 1501 when a brake operation or the like is performed. The light emitting device 101 according to this embodiment may be used in a head lamp as the lighting unit for an automobile. The automobile is an example of a moving body, and the moving body may be a ship, a drone, an aircraft, a railroad car, an industrial robot, or the like. The moving body may include a body and a lighting unit provided in the body. The lighting unit may inform the current position of the body.

The light emitting device 101 according to this embodiment can be applied to the tail lamp 1501. The tail lamp 1501 may include a protective member that protects the light emitting device 101 which functions as the tail lamp 1501. The protective member has a certain degree of strength, and can be made from any material as long as it is transparent. The protective member may be made from polycarbonate or the like. Further, the protective member may be made from polycarbonate mixed with furandicarboxylic acid derivative, acrylonitrile derivative, or the like.

The automobile 1500 may include a body 1503 and windows 1502 attached thereto. The window may be a window for checking the front or rear of the automobile, or may a transparent display such as a head-up display. The light emitting device 101 according to this embodiment may be used in the transparent display. In this case, the components such as the electrodes included in the light emitting device 101 are formed by transparent members.

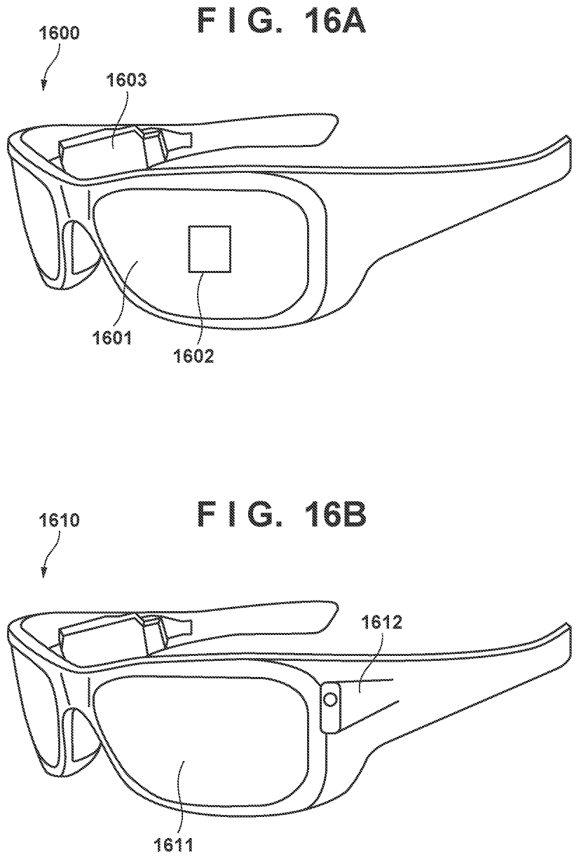

Further application examples of the light emitting device 101 according to this embodiment will be described with reference to FIGS. 16A and 16B. The light emitting device 101 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 16A. An image capturing device 1602 such as a CMOS sensor or an SPAD is provided on the surface side of a lens 1601 of the glasses 1600. In addition, the light emitting device 101 according to this embodiment is provided on the back surface side of the lens 1601.

The glasses 1600 further include a control device 1603. The control device 1603 functions as a power supply that supplies electric power to the image capturing device 1602 and the light emitting device 101 according to each embodiment. In addition, the control device 1603 controls the operations of the image capturing device 1602 and the light emitting device 101. An optical system configured to condense light to the image capturing device 1602 is formed on the lens 1601.

Glasses 1610 (smartglasses) according to one application example will be described with reference to FIG. 16B. The glasses 1610 include a control device 1612, and an image capturing device corresponding to the image capturing device 1602 and the light emitting device 101 are mounted on the control device 1612. The image capturing device in the control device 1612 and an optical system configured to project light emitted from the light emitting device 101 are formed in a lens 1611, and an image is projected to the lens 1611. The control device 1612 functions as a power supply that supplies electric power to the image capturing device and the light emitting device 101, and controls the operations of the image capturing device and the light emitting device 101. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 101 according to the embodiment of the present disclosure can include an image capturing device including a light receiving element, and control a displayed image based on the line-of-sight information of the user from the image capturing device.

More specifically, the light emitting device 101 decides a first visual field region at which the user is gazing and a second visual field region other than the first visual field region based on the line-of-sight information. The first visual field region and the second visual field region may be decided by the control device of the light emitting device 101, or those decided by an external control device may be received. In the display region of the light emitting device 101, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 101, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 101, the image capturing device, or an external device. If the external device holds the AI program, it is transmitted to the light emitting device 101 via communication.

When performing display control based on line-of-sight detection, smartglasses further including an image capturing device configured to capture the outside can be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-037030, filed Mar. 10, 2023, which is hereby incorporated by reference herein in its entirety.

What is claimed is:

1. A semiconductor device comprising:
a first wiring layer including a first wiring pattern;
a second wiring layer arranged between the first wiring layer and a surface of a substrate and including a second wiring pattern and a third wiring pattern:
a first plug connecting the first wiring pattern and the second wiring pattern:
a capacitive element including a first electrode arranged between the first wiring layer and the second wiring layer and a second electrode arranged at a position farther apart from the substrate than the first electrode; and
a second plug connecting the first electrode and the third wiring pattern,
wherein an angle between a side surface of the second plug and an upper surface of the third wiring pattern is not more than 75°.

2. The device according to claim 1, wherein a width of the second plug in a direction parallel to the surface of the substrate increases as a distance between the width of the second plug and the surface of the substrate increases.

3. The device according to claim 1, wherein
the third wiring pattern contains copper, and
the second plug contains tungsten.

4. The device according to claim 1, wherein a height of the second plug is not more than 200 nm.

5. The device according to claim 1, wherein an aspect ratio between a height of the second plug and a surface of the second plug in contact with the first electrode is not more than 1.

6. The device according to claim 1, wherein letting θ be an angle between a side surface of the second plug and an upper surface of the third wiring pattern and H be a height of the second plug, a relationship given by
(500/H)sin² θ≤2.50
is satisfied.

7. The device according to claim 1, wherein an angle between a side surface of the first plug and an upper surface of the second wiring pattern is larger than an angle between the side surface of the second plug and the upper surface of the third wiring pattern.

8. The device according to claim 1, wherein the second electrode is arranged in the first wiring layer.

9. The device according to claim 1, wherein
the second electrode is arranged between the first wiring layer and the first electrode,
the first wiring layer further includes a fourth wiring pattern, and
the semiconductor device further comprises a third plug that connects the fourth wiring pattern and the second electrode.

10. The device according to claim 9, wherein the fourth wiring pattern and the third plug have a dual damascene structure, and contain copper.

11. The device according to claim 9, wherein an angle between a side surface of the third plug and an upper surface of the second electrode is larger than an angle between a side surface of the second plug and an upper surface of the third wiring pattern.

12. A semiconductor device comprising:
a first wiring layer including a first wiring pattern and a fourth wiring pattern;
a second wiring layer arranged between the first wiring layer and a surface of a substrate and including a second wiring pattern;
a first plug connecting the first wiring pattern and the second wiring pattern;
a capacitive element including a second electrode arranged between the first wiring layer and the second wiring layer and a first electrode arranged between the second electrode and the substrate; and
a third plug connecting the fourth wiring pattern and the second electrode,
wherein an angle between a side surface of the third plug and an upper surface of the second electrode is not more than 75°.

13. The device according to claim 12, wherein a width of the third plug in a direction parallel to the surface of the substrate increases as a distance between the width of the third plug and the surface of the substrate increases.

14. The device according to claim 12, wherein
the second electrode contains copper, and
the third plug contains tungsten.

15. The device according to claim 12, wherein a height of the third plug is not more than 200 nm.

16. The device according to claim 12, wherein an aspect ratio between a height of the third plug and a surface of the third plug in contact with the fourth wiring pattern is not more than 1.

17. The device according to claim 12, wherein letting θ be an angle between a side surface of the third plug and an upper surface of the second electrode and H be a height of the third plug, a relationship given by
(500/H)sin² θ≤2.50
is satisfied.

18. The device according to claim 12, wherein an angle between a side surface of the first plug and an upper surface of the second wiring pattern is larger than an angle between a side surface of the third plug and an upper surface of the second electrode.

19. The device according to claim 12, wherein the first electrode is arranged in the second wiring layer.

20. The device according to claim 12, wherein
the first electrode is arranged between the second electrode and the second wiring layer,
the second wiring layer further includes a third wiring pattern, and
the semiconductor device further comprises a second plug that connects the first electrode and the third wiring pattern.

21. The device according to claim 20, wherein an angle between a side surface of the second plug and an upper surface of the third wiring pattern is larger than an angle between a side surface of the third plug and an upper surface of the second electrode.

22. The device according to claim 1, wherein
the second electrode is arranged between the first wiring layer and the first electrode,
the first wiring layer further includes a fourth wiring pattern,
the semiconductor device further comprises a third plug that connects the fourth wiring pattern and the second electrode, and
an angle between a side surface of the third plug and an upper surface of the second wiring pattern is not more than 75°.

23. The device according to claim 22, wherein a width of the second plug in a direction parallel to the surface of the substrate increases as a distance between the width of the second plug and the surface of the substrate increases, and a width of the third plug in the direction parallel to the surface of the substrate increases as a distance between the width of the third plug and the surface of the substrate increases.

24. The device according to claim 1, wherein a pixel including a light emitting element is further arranged.

25. The device according to claim 24, wherein
the pixel further includes a driving transistor configured to supply a current according to a luminance signal to the light emitting element, and
the capacitive element is arranged in the pixel to hold the luminance signal written in the driving transistor.

26. An image forming device comprising a photosensitive member, an exposure light source configured to expose the photosensitive member, a developing unit configured to apply a developing agent to the exposed photosensitive member, and a transfer device configured to transfer an image developed by the developing unit to a print medium,
wherein the exposure light source includes the semiconductor device according to claim 24.

27. A display device comprising the semiconductor device according to claim 24, and an active element connected to the semiconductor device.

28. A photoelectric conversion device comprising an optical unit including a plurality of lenses, an image sensor configured to receive light having passed through the optical unit, and a display unit configured to display an image,
wherein the display unit displays an image captured by the image sensor, and includes the semiconductor device according to claim 24.

29. An electronic apparatus comprising a housing provided with a display unit, and a communication unit provided in the housing and configured to perform external communication,
wherein the display unit includes the semiconductor device according to claim 24.

30. An illumination device comprising a light source, and at least one of a light diffusion unit and an optical film,
wherein the light source includes the semiconductor device according to claim 24.

31. A moving body comprising a body, and a lighting unit provided in the body,
wherein the lighting unit includes the semiconductor device according to claim 24.

32. A wearable device comprising a display device configured to display an image,
wherein the display device includes the semiconductor device according to claim 24.
